(19) United States
(12) Patent Application Publication
(10) Pub. No.: US 2005/0051102 A1
(43) Pub. Date: Mar. 10, 2005

(54) Apparatus for processing substrate in chamber and maintenance method therefor

(75) Inventors: Toru Sato, Kyoto (JP); Jun Watanabe, Kyoto (JP)

Correspondence Address: OSTROLENK FABER GERB & SOFFEN, 1180 AVENUE OF THE AMERICAS, NEW YORK, NY, 100368403, US

(73) Assignee: Dainippon Screen Mfg. Co., Ltd.

(21) Appl. No.: 10/931,434

(22) Filed: Sep. 1, 2004

(30) Foreign Application Priority Data
Sep. 10, 2003 (JP) 2003-318087

(51) Int. Cl. C23C 16/00

(52) U.S. Cl. 118/729; 118/733

(57) ABSTRACT

A thermal processing apparatus (1) comprises a chamber body (6) having an upper opening (60), a transparent plate attached to the upper opening (60) to close the upper opening (60), a holding part (7) for holding and heating a substrate in the inside of the chamber body (6) and a holding-part moving mechanism (4) for moving the holding part (7) up and down. In performing maintenance of the thermal processing apparatus (1), the transparent plate is removed from the chamber body (6) and then the holding part (7) is moved by the holding-part moving mechanism (4) up to a position where a lower surface (77) of the holding part (7) is higher than an upper surface (69) of an edge of the upper opening (60). This allows maintenance for the inside of the chamber body (6) from a gap (601) between the holding part (7) and the chamber body (6) without removing the holding part (7) from the chamber body (6).

### BACKGROUND OF THE INVENTION

1. Field of the Invention

The present invention relates to an apparatus for processing a substrate in a chamber and a maintenance method for the apparatus.

2. Description of the Background Art

Conventionally, in a process of manufacturing semiconductor substrates, glass substrates for display devices or the like (hereinafter, referred to simply as “substrates”), various processings are performed for the substrates in chambers. For example, in a process of forming an oxide film or the like, a processing through heating is generally performed for a substrate in a chamber and a rapid thermal process (hereinafter, referred to as “RTP”) is used as a method of thermal processing. In the RTP, by heating the substrate in the chamber with halogen lamps or the like to raise the temperature thereof up to a predetermined temperature in a short time, it is possible to perform processings which have been hard to execute by a conventional long thermal processing with electric furnaces, such as thinning of an insulating film such as an oxide film, suppressing of diffusion of impurities (or dopants) which are implanted by ion implantation in an activation process, or the like. In recent proposed is a technique for heating a substrate in a shorter time with flash lamps as a heating source for a substrate. As other typical apparatuses for processing a substrate in a chamber, a CVD (Chemical Vapor Deposition) apparatus, an apparatus using plasma or the like may be used.

In these apparatuses for processing a substrate in a chamber, it is necessary to keep the inside of the chamber clean lest unnecessary particles are deposited on a surface of the substrates to degrade the quality of the substrate, and various techniques for facilitating maintenance for the inside of the chamber are proposed.

Japanese Patent Application Laid Open Gazette No. 10-237658, for example, discloses a technique for easily positioning a susceptor in attaching the susceptor used for supporting a substrate in a vacuum chamber, by protruding a column of the susceptor having a noncircular tip from the inside of the vacuum chamber to the outside and placing the tip of the column onto a positioning plate having a noncircular insertion opening.

A pamphlet of WO01/088971 shows a chamber whose ceiling is an upper electrode unit consisting an upper assembly and a lower assembly and discloses a technique that in maintenance for the inside of the chamber, the upper assembly and the lower assembly are joined together with a locking mechanism and moved upward with an up-and-down moving mechanism to open the chamber.

In maintenance for the inside of a chamber, some operations require taking out components from the inside of the chamber. Especially, in a thermal processing apparatus for executing a thermal processing with flash lamps, a substrate is sometimes broken due to rapid thermal expansion of its surface into pieces to be scattered in the chamber since a flash of the flash lamps raises the surface temperature of the substrate in an extremely short time. In such a case, in order to perform maintenance (cleaning) of the inside of the chamber to recover the apparatus, it is necessary to take off a large number of components including heavy ones such as a holding part for holding the substrate out of the chamber. Further, after the maintenance is finished, it is also necessary to equip the components which have been taken out from the inside of the chamber again through accurate positioning and execute operations for adjustment such as checking on whether the apparatus should normally operate or not, and this imposes an burden on an operator and requires a lot of working hours. In recent, with upsizing of a substrate, components in the chamber (especially, the holding part for holding the substrate) are upsized, and therefore maintenances needing detachment and attachment of these components require further labor and time.

### SUMMARY OF THE INVENTION

It is an object of the present invention to perform maintenance for the inside of a chamber without removing a holding part used for holding a substrate in a substrate processing apparatus for processing a substrate in the chamber.

According to the present invention, a substrate processing apparatus comprises a chamber body forming a chamber which is a space for processing a substrate and having an opening in its upper portion, a closing member attached to the opening, for closing the opening, a holding part for holding a substrate in the chamber, and a moving mechanism for moving a lower surface of the holding part up to a level higher than an upper surface of an edge of the opening while the closing member is not attached to the opening.

In the present invention, it is possible to perform maintenance for the inside of the chamber body without removing the holding part.

Preferably, the lower surface of the holding part is moved by the moving mechanism up to a level higher than the upper surface of the edge of the opening by 100 mm or more. It thereby becomes possible for an operator to perform maintenance with his hands put into the chamber body.

The substrate processing apparatus is particularly suitable for an apparatus using flash lamps to emit light to a substrate through a closing member.

The present invention is also intended for a maintenance method in the substrate processing apparatus for processing a substrate in a chamber.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a view showing a construction of a thermal processing apparatus in accordance with one preferred embodiment;

FIG. 2 is a cross section showing a gas path;

FIG. 3 is a cross section showing a holding part and a shaft;

FIG. 4 is a plan view showing a hot plate;

FIG. 5 is a cross section showing resistance heating wires;

FIG. 6 is a flowchart showing an operation flow of the thermal processing apparatus during processing operation;

FIG. 7 is a view showing a flow of gas;

FIG. 8 is a view showing a construction of the thermal processing apparatus;

FIGS. 9 and 10 are flowcharts showing an operation flow of the thermal processing apparatus during maintenance;

FIGS. 11 and 12 are views each showing a light emitting part, a chamber body and a emitting-part moving mechanism; and

FIGS. 13 and 14 are views each showing a construction of the thermal processing apparatus.

### DESCRIPTION OF THE PREFERRED EMBODIMENTS

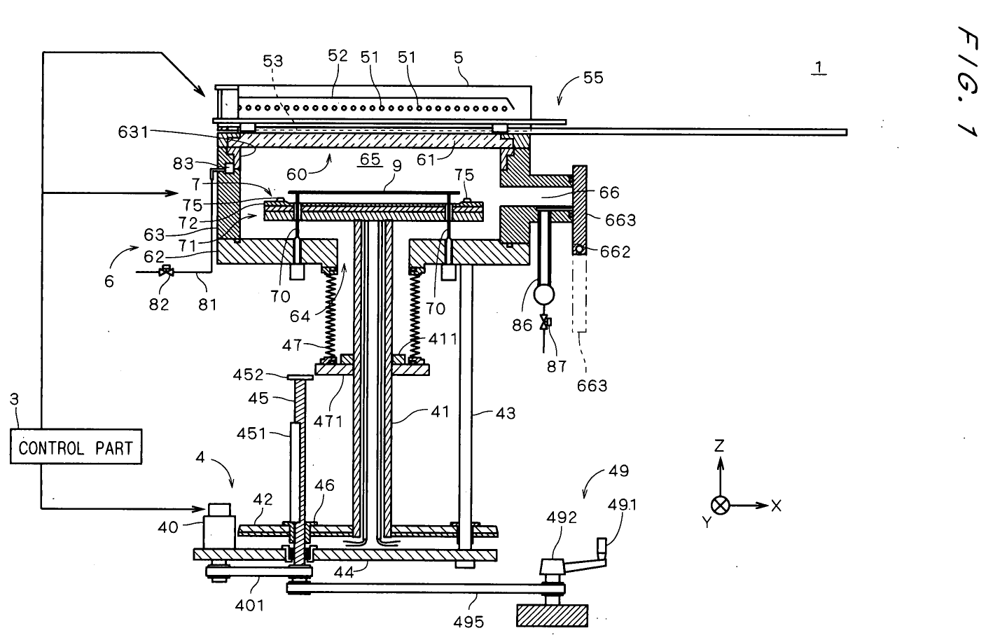

FIG. 1 is a view showing a construction of a thermal processing apparatus 1 in accordance with one preferred embodiment of the present invention. The thermal processing apparatus 1 is an apparatus for performing a processing accompanied with heating through irradiating a semiconductor substrate 9 (hereinafter, referred to as “substrate 9”) with light.

The thermal processing apparatus 1 comprises a chamber side part 63 having a substantially-cylindrical inner wall and a chamber bottom 62 covering a lower portion of the chamber side part 63, which constitute a chamber body 6 forming a space (hereinafter, referred to as “chamber”) 65 for thermally processing the substrate 9 and comprising an opening (hereinafter, referred to as “upper opening”) 60 in its upper portion.

The thermal processing apparatus 1 further comprises a transparent plate 61 which is a closing member attached to the upper opening 60 for closing the upper opening 60, a substantially disk-shaped holding part 7 for holding the substrate 9 inside the chamber body 6 and executing a preliminary heating on the substrate 9, a holding-part moving mechanism 4 for vertically moving the holding part 7 with respect to a bottom of the chamber body, i.e., the chamber bottom 62, a light emitting part 5 for heating the substrate 9 by emitting light through the transparent plate 61 to the substrate 9 held by the holding part 7, and a control part 3 for controlling these constituent elements to perform a thermal processing.

The transparent plate 61 is formed of a material having infrared transmissivity such as quartz and serves as a chamber window for transmitting the light from the light emitting part 5 to the chamber 65. The chamber bottom 62 and the chamber side part 63 are formed of metal material such as stainless steel having excellent strength and heat resistance, and a ring 631 in an upper portion of an inner side surface of the chamber side part 63 is formed of aluminum (Al) alloy or the like having more excellent resistance than stainless steel to degradation caused by light irradiation.

On the chamber bottom 62, a plurality of (in the present preferred embodiment, three) support pins 70 stand for supporting the substrate 9 from its lower surface (on the side opposite to a side irradiated with light by the light emitting part 5) through the holding part 7. The support pin 70 is formed of, e.g., quartz, and easy to replace as it is fixed from the outside of the chamber body 6.

The chamber side part 63 has a transfer opening 66 used for loading and unloading of the substrate 9, and the transfer opening 66 is made openable/closable by a gate valve 663 which rotates about an axis 662. On a portion of the chamber side part 63 which is opposite to the transfer opening 66, a gas introduction path 81 is formed to introduce a process gas (e.g., inert gas such as nitrogen (N₂) gas, helium (He) gas or argon (Ar) gas, or oxygen (O₂) gas) into the chamber 65, whose one end is connected to a not-shown gas supply mechanism through a valve 82 and other end is connected to a gas introduction channel 83 formed inside the chamber side part 63. In the transfer opening 66 formed is a gas exhaust path 86 for exhausting air in the chamber, which is connected to a not-shown gas exhaust mechanism through a valve 87.

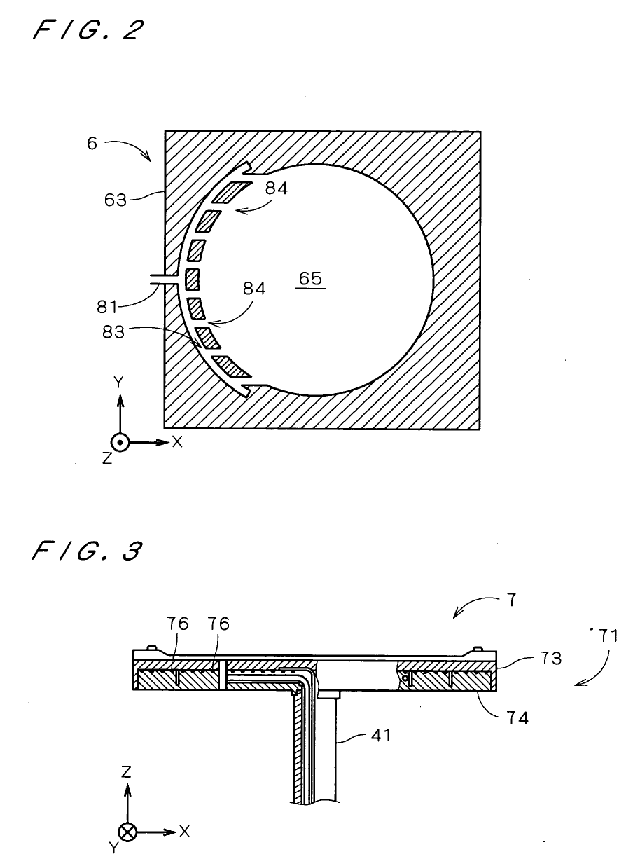

FIG. 2 is a cross section of the chamber body 6 taken along a plane perpendicular to the Z direction at a position of the gas introduction channel 83. As shown in FIG. 2, the gas introduction channel 83 is so formed as to cover about one-third of a perimeter of the chamber side part 63 on the side opposite to the transfer opening 66 of FIG. 1, and the process gas introduced by the gas introduction channel 83 through the gas introduction path 81 is supplied to the inside of the chamber 65 from a plurality of gas supply holes 84.

The holding-part moving mechanism 4 of FIG. 1 has a substantially-cylindrical shaft 41, a moving plate 42, guide members 43 (in the present preferred embodiment, three guide members are arranged around the shaft 41), a fixed plate 44, a ball screw 45, a nut 46 and a motor 40. In the chamber bottom 62 which is lower portion of the chamber body 6, an opening (hereinafter, referred to as “lower opening”) 64 of substantial circle having a diameter smaller than that of the holding part 7 is formed and the shaft 41 of stainless steel is inserted into the lower opening 64 and connected to a lower surface of the holding part 7 (a hot plate 71) to support the holding part 7.

The nut 46 into which the ball screw 45 is inserted is fixed to the moving plate 42, and the moving plate 42 is made vertically movable, being guided by the guide members 43 which are fixed to the chamber bottom 62, extending downward, and the moving plate 42 is connected to the holding part 7 through the shaft 41.

The motor 40 is disposed on the fixed plate 44 attached to lower end portions of the guide members 43 and connected to the ball screw 45 through a timing belt 401. When the holding part 7 is vertically moved by the holding-part moving mechanism 4, the motor 40 serving as a driving part is controlled by the control part 3 to rotate the ball screw 45, thereby moving the moving plate 42 to which the nut 46 is fixed along the guide members 43. As a result, the shaft 41 is moved along the Z direction of FIG. 1 and the holding part 7 connected to the shaft 41 smoothly moves up and down inside the chamber body 6 during the thermal processing for the substrate 9.

A mecha-stopper 451 of substantial semicylinder (shape of cylinder cut half along a longitudinal direction) stands on an upper surface of the moving plate 42 along the ball screw 45, and even if the moving plate 42 moves up over a predetermined rising limit due to some abnormal conditions, it is possible to prevent abnormal rise of the moving plate 42 as an upper end of the mecha-stopper 451 is pushed against an end plate 452 which is provided at an end portion of the ball screw 45. This prevents the holding part 7 from moving up over a predetermined position below the transparent plate 61 to avoid the collision between the holding part 7 and the transparent plate 61.

The holding-part moving mechanism 4 has a manual moving part 49 for manually moving the holding part 7 up and down during the maintenance for the inside of the chamber body 6. The manual moving part 49 has a handle 491 and a rotation axis 492, and with rotation of the rotation axis 492 through the handle 491, the ball screw 45 connected to the rotation axis 492 through a timing belt 495 is rotated to move the holding part 7 up and down. Though the handle 491 is seen on the side for loading/unloading of substrates in the thermal processing apparatus 1 in FIG. 1, for convenience of illustration, it is preferable that the handle 491 should be disposed on a side surface of the thermal processing apparatus 1 in the Y-axis direction.

The chamber bottom 62 is provided at its lower side with extensible bellows 47 which can so extend downward as to surround the shaft 41, whose upper end is connected to the lower surface of the chamber bottom 62. The other end of the bellows 47 is provided with a bellows lower-end plate 471, which is screwed onto a brim-like member 411 attached to the shaft 41, to thereby keep the inside of the chamber 65 airtight. The bellows 47 is contracted when the holding part 7 is moved up with respect to the chamber bottom 62 by the holding-part moving mechanism 4 and extended when the holding part 7 is moved down.

The holding part 7 has a hot plate 71 used for preheating (assist heating) of the substrate 9 and a susceptor 72 disposed on an upper surface of the hot plate 71 (a surface on the side where the holding part 7 holds the substrate 9), and as discussed above, the shaft 41 used for vertically moving the holding part 7 is connected to the lower surface of the holding part 7 (the hot plate 71). The susceptor 72 is formed of quartz (may be also formed of aluminum nitride (AlN) or the like), and pins 75 are provided on an upper surface of the susceptor 72 to prevent the substrate 9 from deviating from a predetermined position. The susceptor 72 is disposed on the hot plate 71 in surface-to-surface contact between the lower surface of the susceptor 72 and the upper surface of the hot plate 71, so that the susceptor 72 serves to diffuse and conduct thermal energy from the hot plate 71 and can be detached from the hot plate 71 for cleaning during maintenance.

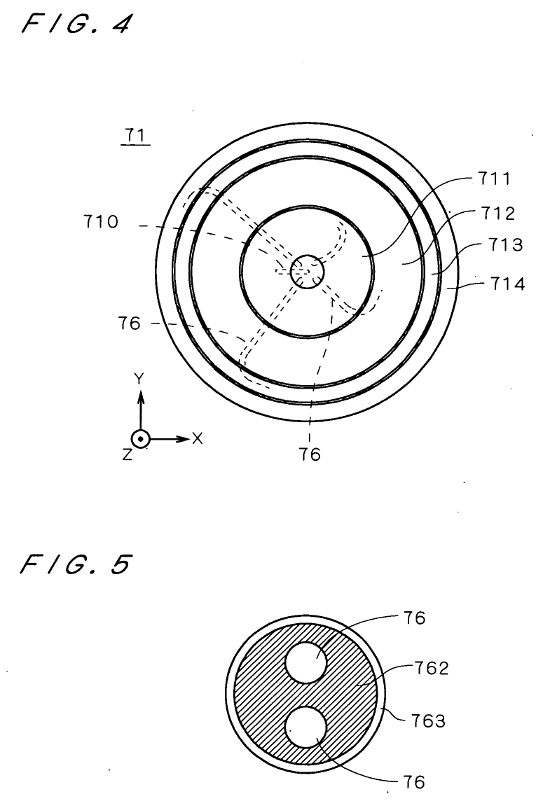

FIG. 3 is a cross section showing the holding part 7 and the shaft 41. The hot plate 71 has an upper plate 73 and a lower plate 74 both of stainless steel, and resistance heating wires 76 such as nichrome wires for heating the hot plate 71 are provided between the upper plate 73 and the lower plate 74, which are filled with conductive nickel brazing filler metals and sealed. End portions of the upper plate 73 and the lower plate 74 are bonded to each other by brazing.

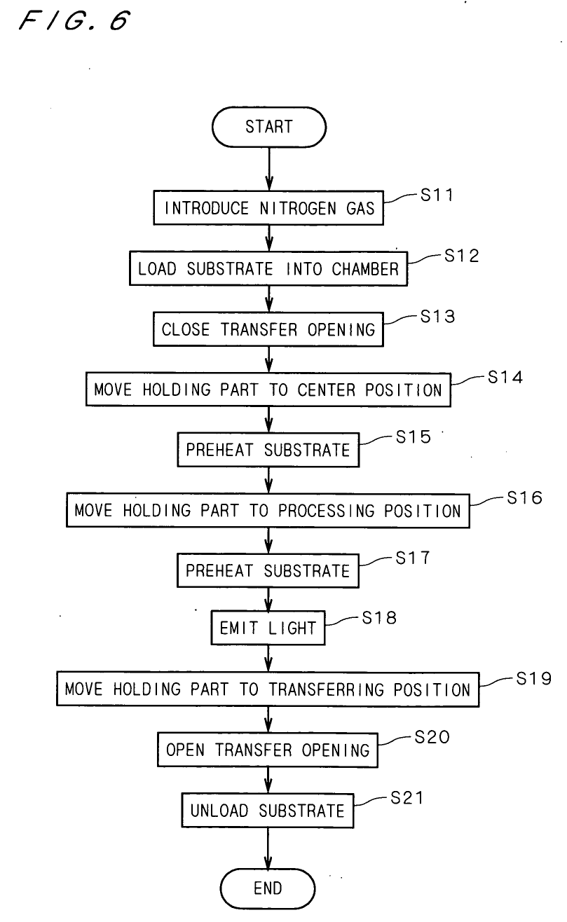

FIG. 4 is a plan view showing the hot plate 71. As shown in FIG. 4, the hot plate 71 is concentrically divided into four zones 711 to 714, and a gap is provided between one zone and the adjacent zone. The zones 711 to 714 are provided with the resistance heating wires 76 which are independent from one another in a rounding manner and heated by these resistance heating wires 76, respectively.

The innermost zone 711 is provided with a sensor 710 for measuring the temperature of the zone 711 with a thermocouple, and the sensor 710 is connected to the control part 3 through the inside of the substantially-cylindrical shaft 41 (see FIG. 3). When the hot plate 71 is heated, the control part 3 controls the amount of power supply for the resistance heating wire 76 provided in the zone 711 so that the temperature of the zone 711 which is measured by the sensor 710 should become a predetermined temperature. The control part 3 controls the temperature of the zone 711 by PID (Proportional, Integral, Differential) control. The amount of power supply for the resistance heating wire 76 provided in each of the zones 712 to 714 is determined on the basis of the amount of power supply for that in the zone 711, according to a predefined correspondence table (correspondence between the amount of power supply for the zone 711 and that required to make the temperatures of the other zones 712 to 714 equal to that of the zone 711). In the hot plate 71, the temperature of the zone 711 is continuously measured until the thermal processing for the substrate 9 (if a plurality of substrates 9 are successively processed, the thermal processing for all the substrates 9) is finished, and with this control, the temperatures of the zones 711 to 714 are kept to be a target temperature.

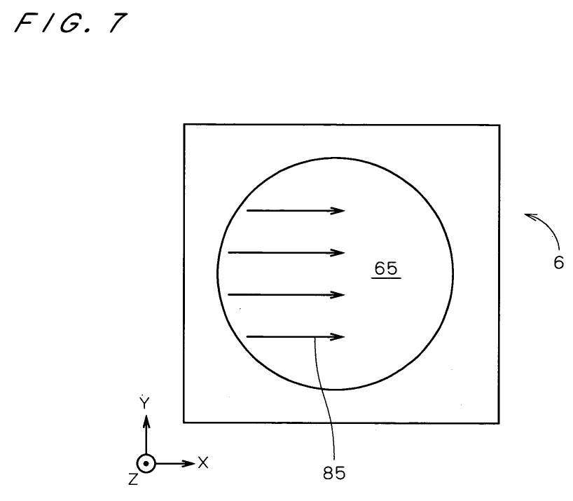

The respective resistance heating wires 76 provided in the zones 711 to 714 are connected to a power supply source (not shown) through the inside of the shaft 41, and from the power supply source to the respective zones, two parts of the resistance heating wire 76 from and to the power supply source are so arranged as to be electrically insulated from each other inside a stainless tube 763 filled with an insulative material 762 such as magnesia (magnesium oxide), as shown in FIG. 5. The inside of the shaft 41 is open to the air.

The light emitting part 5 of FIG. 1 has a plurality of (in the present preferred embodiment, thirty) xenon flash lamps (hereinafter, referred to simply as “flash lamps”) 51, a reflector 52 and a light diffusion plate 53. A plurality of flash lamps 51 are rod lamps of long cylindrical shape and arranged so that their longitudinal directions (the Y direction of FIG. 1) should be parallel to one another along a main surface of the substrate 9 held by the holding part 7. The reflector 52 is so provided as to entirely cover upper portions of the flash lamps 51 and its surface is roughened by abrasive blasting to have a satin finish. The light diffusion plate 53 is formed of fused quartz whose surface is photodiffused and disposed on a lower surface of the light emitting part 5 with a predetermined gap between itself and the transparent plate 61. The thermal processing apparatus 1 further comprises an emitting-part moving mechanism 55 used for relatively moving the light emitting part 5 with respect to the chamber body 6 during maintenance. A constitution and an operation of the emitting-part moving mechanism 55 will be discussed later.

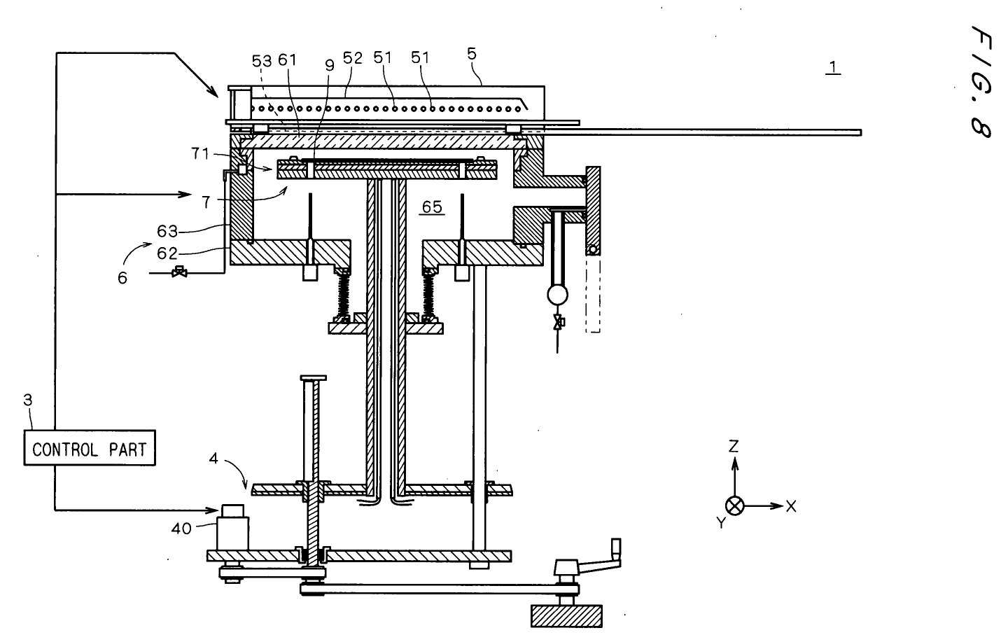

FIG. 6 is a flowchart showing an operation flow of the thermal processing apparatus 1 for performing a thermal processing on the substrate 9. In the present preferred embodiment, the substrate 9 is a semiconductor substrate which is implanted with impurities by ion implantation and the implanted impurities are activated by the thermal processing in the thermal processing apparatus 1.

To perform a thermal processing on the substrate 9 in the thermal processing apparatus 1, first, the holding part 7 is arranged near the chamber bottom 62 as shown in FIG. 1. Hereinafter, the position of the holding part 7 in the chamber 65 shown in FIG. 1 is referred to as “transferring position”. When the holding part 7 stays at the transferring position, tips of the support pins 70 are positioned above the holding part 7, through the holding part 7. Next, the valves 82 and 87 are opened to introduce room-temperature nitrogen gas into the chamber 65 (Step S11). Subsequently, the transfer opening 66 is opened and the substrate 9 is loaded into the chamber 65 through the transfer opening 66 by a transfer robot (not shown) controlled by the control part 3 (Step S12) and put on a plurality of support pins 70.

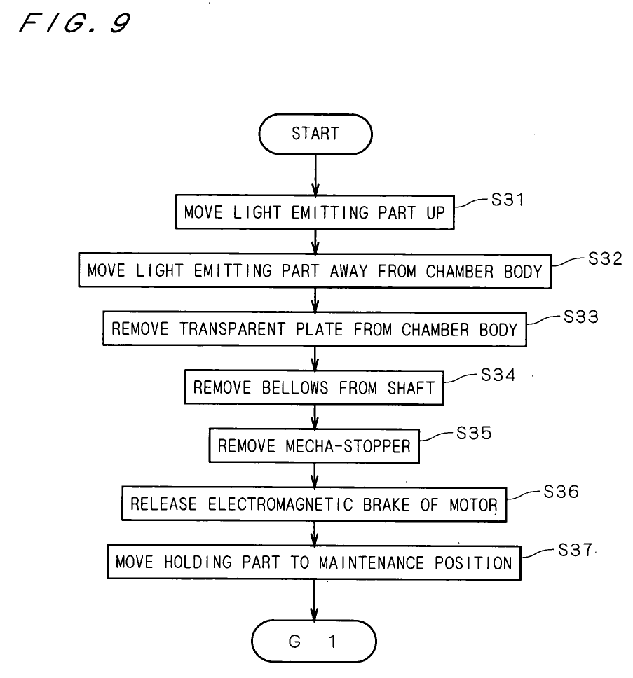

FIG. 7 is a view abstractly showing the chamber body 6 of FIG. 2. The amount of nitrogen gas to be purged into the chamber 65 in loading of the substrate 9 is about 40 l/min, and the supplied nitrogen gas flows to a direction indicated by the arrow 85 of FIG. 7 in the chamber 65 and exhausted through the gas exhaust path 86 and the valve 87 of FIG. 1 by utility exhaust. Part of the nitrogen gas supplied to the chamber 65 is exhausted also from an exhaust port (not shown) which is provided at the inner side of the bellows 47. In each of the following steps, the nitrogen gas is continuously supplied to and exhausted from the chamber 65 and the amount of nitrogen gas to be purged is changed in accordance with the process steps for the substrate 9.

When the substrate 9 is loaded into the chamber 65, the gate valve 663 of FIG. 1 closes the transfer opening 66 (Step S13), and the holding-part moving mechanism 4 moves the holding part 7 up to a position near the center (hereinafter, referred to as “center position”) along the vertical direction (the Z direction of FIG. 1) of the chamber 65 (Step S14). At this time, the substrate 9 is passed from the support pins 70 to the susceptor 72 of the holding part 7 and held by the susceptor 72. The holding part 7 has been heated up to a predetermined temperature by the resistance heating wires 76 inside the hot plate 71 (between the upper plate 73 and the lower plate 74) and preheating of the substrate 9 is performed by bringing the substrate 9 into contact with the holding part 7 (the susceptor 72) (Step S15), to thereby allows gradual increase in temperature of the substrate 9. In the holding part 7, the substrate 9 is uniformly preheated since the thermal energy from the hot plate 71 is diffused by the susceptor 72.

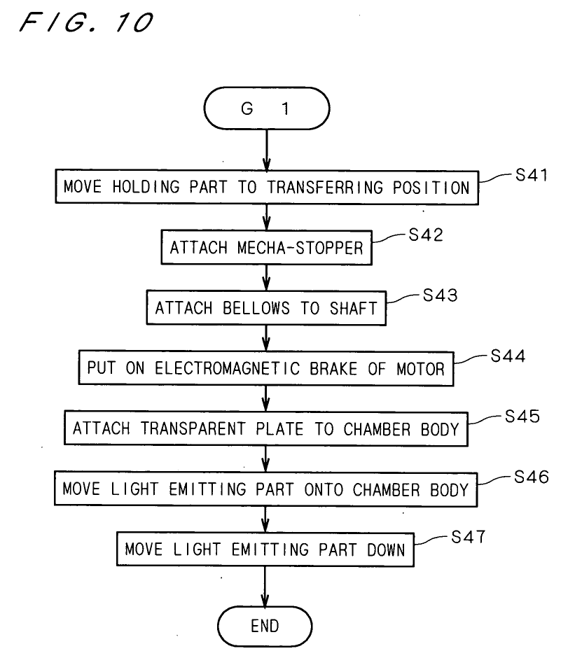

After the preheating is performed for about one second at the center position, the holding part 7 is moved by the holding-part moving mechanism 4 up to a position near the transparent plate 61 (hereinafter, referred to as “processing position”) as shown in FIG. 8 (Step S16) and further preheated for about sixty seconds at this position, and the temperature of the substrate 9 thereby rises up to a predetermined temperature through preheating (hereinafter, referred to as “setting temperature”) (Step S17). The setting temperature is in a range from about 200° C. to 600° C. where there is no possibility that the impurities implanted in the substrate 9 should be diffused, preferably from about 350° C. to 550° C. The distance between the holding part 7 and the transparent plate 61 can be arbitrarily controlled by controlling the amount of rotation of the motor 40 in the holding-part moving mechanism 4.

After that, while the holding part 7 stays at the processing position, the control part 3 controls the light emitting part 5 to emit flash light to the substrate 9 (Step S18). At this time, part of the light emitted from the flash lamps 51 of the light emitting part 5 goes through the light diffusion plate 53 and the transparent plate 61 directly towards the inside of the chamber 65 and the other of the light is reflected on the reflector 52, going through the light diffusion plate 53 and the transparent plate 61 to the inside of the chamber 65, which are used to irradiate the substrate 9 to be heated (hereinafter, the heating to raise the surface temperature of the substrate 9 up to the processing temperature is referred to as “main heating” for being distinguished from preheating). Since the main heating is performed by light irradiation, it is possible to increase and decrease the surface temperature of the substrate 9 in a short time.

The light emitted from the light emitting part 5, i.e., the flash lamps 51 is an extremely short and strong flash whose irradiation time ranges from about 0.1 to 10 milliseconds, which is obtained by converting electrostatic energy stored in advance into an extremely short light pulse, and with the light emitted from the flash lamps 51, the surface temperature of the substrate 9 which is mainly heated momentarily rises up to the processing temperature ranging from about 1000° C. to 1100° C. and quickly falls after activating the impurities implanted in the substrate 9. Thus, in the thermal processing apparatus 1, since the surface temperature of the substrate 9 can increase and decrease in an extremely short time, it is possible to activate the impurities implanted in the substrate 9 while suppressing diffusion of the impurities caused by heating (the diffusion is sometimes referred to as broadening of profile of impurities in the substrate 9).

By preheating of the substrate 9 with the holding part 7 prior to its main heating, it is possible to quickly raise the surface temperature of the substrate 9 with irradiation of light from the flash lamps 51 up to the processing temperature.

The thermal processing apparatus 1 comprises various constituents for cooling (not shown) so as to prevent excessive increase in temperature of the chamber body 6 and the light emitting part 5 with thermal energy generated from the flash lamps 51 and the hot plate 71 during the thermal processing for the substrate 9. For example, the chamber side part 63 and the chamber bottom 62 in the chamber body 6 are provided with a water-cooling tube, and the light emitting part 5 is provided therein with a supply tube for supplying air and an exhaust tube with silencer to form an air-cooled structure. Compressed air is supplied into the gap between the transparent plate 61 and (the light diffusion plate 53 of) the light emitting part 5, to thereby cool the light emitting part 5 and the transparent plate 61.

After the main heating is finished, the holding part 7 stays waiting for about ten seconds at the processing position and then is moved down to the transferring position shown in FIG. 1 again by the holding-part moving mechanism 4 (Step S19), and the substrate 9 is transferred from the holding part 7 to the support pins 70. Subsequently, the transfer opening 66 which has been closed by the gate valve 663 is opened (Step S20) and the substrate 9 placed on the support pins 70 is unloaded by the transfer robot (Step S21). Thus, a series of operations for thermal processing on the substrate 9 by the thermal processing apparatus 1 is completed.

As discussed above, the nitrogen gas is continuously supplied into the chamber 65 during the thermal processing on the substrate 9 by the thermal processing apparatus 1, and the amount of nitrogen gas to be purged is 30 l/min when the holding part 7 stays at the processing position (in other words, during a period from the time when the holding part 7 is moved to the processing position after the preheating for about one second at the center position to the time when the waiting for about ten seconds after light irradiation is finished) and 40 l/min when the holding part 7 stays at any position other than the processing position.

In the thermal processing apparatus 1, when the same thermal processing is performed on a new substrate 9, such operations as loading of the substrate 9 into the chamber 65, light irradiation and unloading of the substrate 9 from the chamber 65 (Steps S12 to S21) are repeated. When a different thermal processing is performed on a new substrate 9, the holding part 7 moves up to the processing position and stays waiting there while various settings are made in accordance with the new thermal processing (such as setting of the amount of nitrogen gas to be purged). By keeping the temperature of the transparent plate 61 to be almost equal to a temperature at the time when the thermal processings are continuously performed, it is possible to keep the quality of processing on the substrate 9 in the new thermal processing.

There are a few cases, however, where in thermal processing using flash lamps, the substrate is broken into pieces and scattered due to quick thermal expansion of the surface irradiated with light since irradiation of light from the flash lamps raises the surface temperature of the substrate in an extremely short time. If there is such a breakage of the substrate 9 in the thermal processing apparatus 1, the broken pieces of the substrate 9 are scattered widely in the chamber 65 and enter the space between the holding part 7 and the chamber bottom 62, and this requires maintenance (in other words, cleaning) for the inside of the chamber 65.

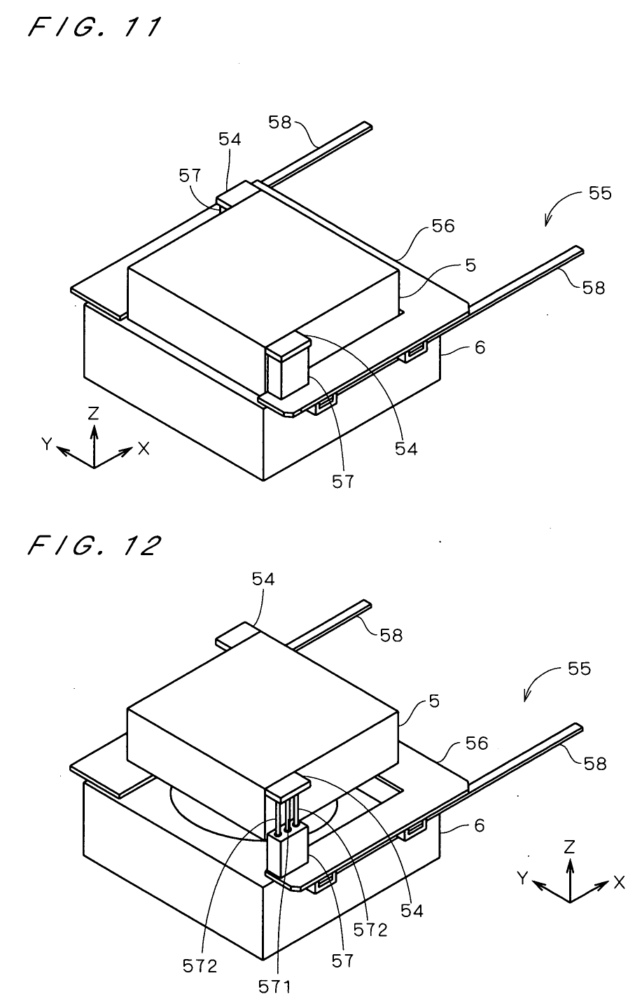

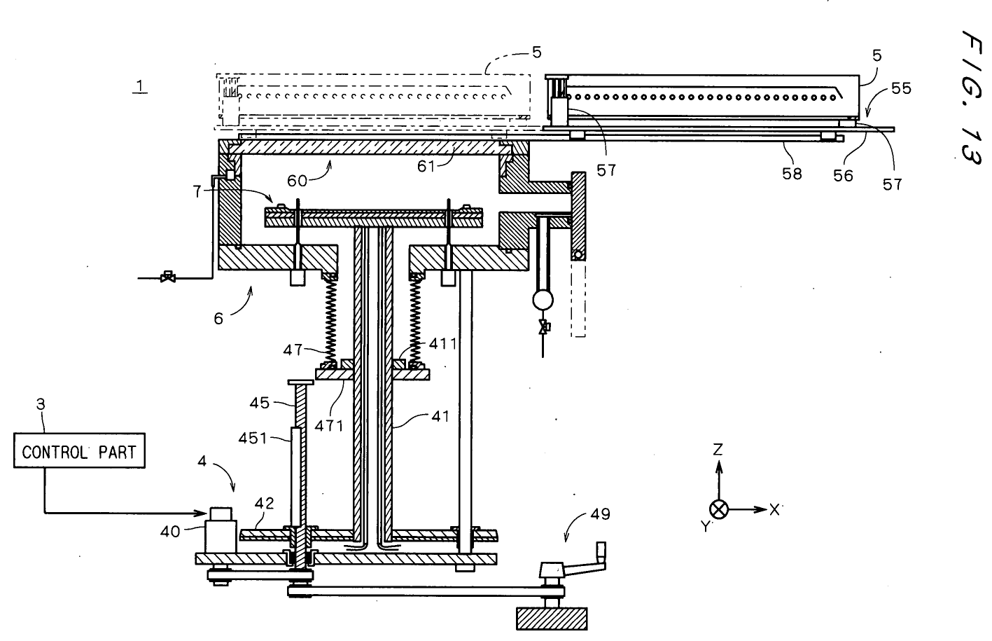

FIGS. 9 and 10 are flowcharts showing an operation flow of the thermal processing apparatus 1 during maintenance. FIGS. 11 and 12 are views each showing the light emitting part 5, the chamber body 6 and the emitting-part moving mechanism 55. Referring to FIGS. 9 to 12 and other figures, the operation of the thermal processing apparatus 1 during maintenance will be discussed.

In maintenance of the thermal processing apparatus 1, first, the control part 3 (see FIG. 1) controls the emitting-part moving mechanism 55 of FIG. 1 to be driven. The emitting-part moving mechanism 55 of FIG. 11 has a substantially U-shaped support plate 56 whose position of vertical direction (the Z direction) with respect to the chamber body 6 is fixed, a plurality of (in the present preferred embodiment, on diagonal lines of the light emitting part 5, two) air cylinders 57 provided on an upper surface of the support plate 56 and a pair of guide rails 58 for holding the support plate 56 movably and guiding it in the X direction of FIG. 11. A substantially U-shaped inner peripheral edge of the support plate 56 is formed slightly larger than an outer peripheral edge of the light emitting part 5. A plurality of air cylinders 57 are coupled to a plurality of brackets 54 fixed on the light emitting part 5. The guide rails 58 are fixed on a frame (not shown) of the thermal processing apparatus 1.

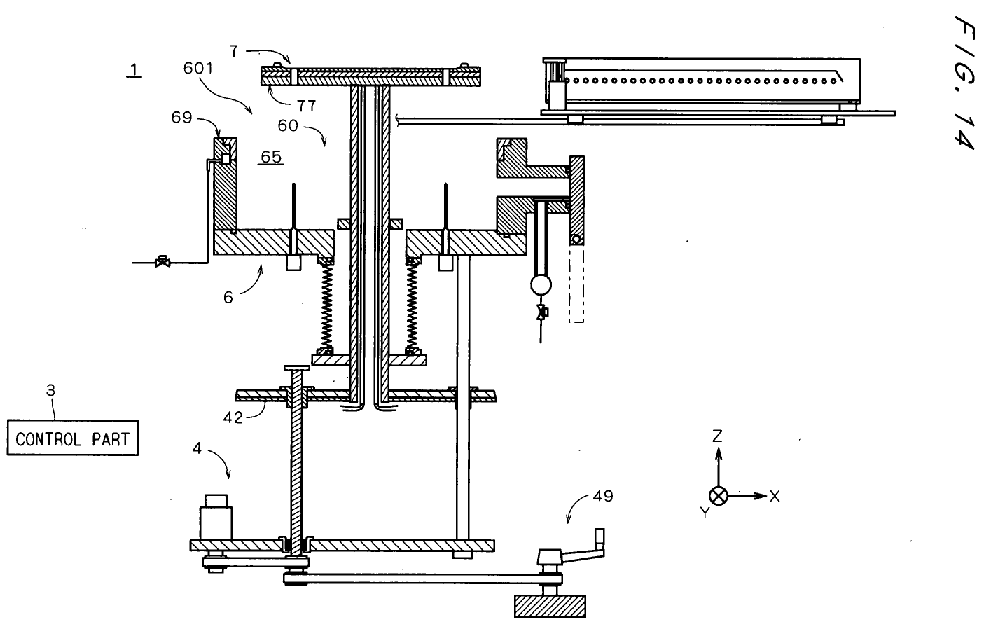

When the control part 3 controls the light emitting part 5 to be driven, a cylinder rod 571 and two rod guides 572 sandwiching the cylinder rod 571 on each air cylinder 57 shown in FIG. 12 moves upward, and the light emitting part 5 coupled thereto through the bracket 54 moves up with respect to the chamber body 6 (Step S31). In a state where the light emitting part 5 stays higher, the light emitting part 5 is moved together with the support plate 56 manually (or by a separately-provided driving mechanism) in a horizontal direction (the (+X) direction) along the guide rails 58 to be escaped from a position on the chamber body 6 which is indicated by the two-dot chain line of FIG. 13 to a position indicated by the solid line (hereinafter, referred to as “escape position”) (Step S32). Subsequently, a ring-like member used for pushing an edge of the transparent plate 61 against the chamber body 6 is removed and the transparent plate 61 is removed from the chamber body 6 by an operator (Step S33), to open the upper opening 60 of the chamber body 6.

Next, attachment pins used for coupling the bellows lower-end plate 471 and the brim-like member 411 of the shaft 41 shown in FIG. 13 is removed to release the fixing of the bellows 47 to the shaft 41 (Step S34), and the mecha-stopper 451 attached to the moving plate 42 is removed (Step S35).

After that, an electromagnetic brake of the motor 40 in the holding-part moving mechanism 4 is released (Step S36), and with rotation of the ball screw 45 by the manual moving part 49, the holding part 7 is moved up, going through the upper opening 60 up to a predetermined position outside the chamber body 6 (hereinafter, referred to as “maintenance position”) as shown in FIG. 14 (Step S37). The holding part 7 is anchored to the maintenance position by locking the moving plate 42 with a plunger (not shown) which is attached to the frame of the thermal processing apparatus 1.

Thus, in the thermal processing apparatus 1 of FIG. 14, while the transparent plate 61 (see FIG. 13) is not attached to the upper opening 60, the holding part 7 is moved by the holding-part moving mechanism 4 up to a level where the lower surface 77 of the holding part 7 (the main surface opposite to the side for holding the substrate 9) becomes higher than an upper surface 69 of the edge of the upper opening 60 and a gap 601 is so formed between the holding part 7 and the chamber body 6 as to extend vertically (in the Z direction of FIG. 14). In the thermal processing apparatus 1, the maintenance of the inside of the chamber body 6 (the chamber 65) is performed through the gap 601 (Step S38).

It is preferably that the width of the gap 601 (i.e., the distance between the lower surface 77 of the holding part 7 and the upper surface 69 of the edge of the upper opening 60 in the Z direction) should be 100 mm or more, in terms of allowing the operator to perform the maintenance with his (her) hands put into the chamber body 6. In other words, by moving the holding part 7 with the holding-part moving mechanism 4 up to the position where its lower surface 77 becomes higher than the upper surface 69 of the edge of the upper opening 60 by 100 mm or more, it is possible for the operator to put his hands into the chamber body 6 for performing maintenance.

If the operator needs to put his arms into the chamber body 6 as the chamber 65 is wide, it is preferable that the vertical width of the gap 601 should be 150 mm or more. If the substrate 9 is a large-sized glass substrate for display, as the chamber 65 becomes still wider, it becomes preferable that the vertical width of the gap 601 should be 300 mm or more in order for the operator to put his head into the chamber body 6 for visual inspection of the inside of the chamber body 6. In the thermal processing apparatus 1, the vertical width of the gap 601 is set to be 150 mm or more (about 157 mm) and this allows the operator to perform maintenance with his arms put into the chamber body 6.

In the thermal processing apparatus 1, since it is necessary to extend the shaft 41 in the Z direction of FIG. 14 in order to enlarge the gap 601, it is preferable that the rise of the holding part 7 should be limited to the minimum. For example, it is preferable that the vertical width of the gap 601 should be 300 mm or less if only hands or arms are put into the gap 601 and should be 600 mm or less if a head is put thereinto.

After the maintenance operation is finished, first, the plunger for locking the moving plate 42 is removed and the holding part 7 is thereby moved from the maintenance position to the transferring position as shown in FIG. 13 (Step S41). The holding part 7 may be moved down by the manual moving part 49 of the holding-part moving mechanism 4, or may be moved down slowly and safely with weights of the holding part 7, the shaft 41 and the like and the resistance of the holding-part moving mechanism 4. Subsequently, the mecha-stopper 451 is attached to the moving plate 42 (Step S42) and the bellows lower-end plate 471 and the brim-like member 411 of the shaft 41 are coupled to each other with the attachment pins (Step S43), and then the motor 40 of the holding-part moving mechanism 4 is put on the electromagnetic brake (Step S44).

Next, the transparent plate 61 is attached to the chamber body 6 to fix the edge of the transparent plate 61 with the ring-like member and the upper opening 60 of the chamber body 6 is thereby closed (Step S45). The light emitting part 5 is moved manually (or by the driving mechanism) together with the support plate 56 in the horizontal direction (the (−X) direction) along the guide rails 58 from the escape position onto the chamber body 6 (Step S46). After that, the control part 3 controls the air cylinders 57 of the emitting-part moving mechanism 55 to move the light emitting part 5 down with respect to the chamber body 6, to complete the maintenance with achieving the state shown in FIG. 1 (without presence of the substrate 9) (Step S47).

Thus, in the thermal processing apparatus 1, since the lower surface 77 of the holding part 7 is moved to a level higher than the upper surface 69 of the edge of the upper opening 60 to form the gap 601 between the holding part 7 and the chamber body 6, it is possible to perform the maintenance of the inside of the chamber body 6 without removing the holding part 7. This makes it possible to reduce time and labor required for the maintenance of the thermal processing apparatus 1 and improve its productivity.

Since the thermal processing apparatus 1 has a structure (T-shaped structure) where the holding part 7 is supported and moved up and down by one shaft 41 having a section smaller than that of the holding part 7, the capacity of a space surrounded by the bellows 47 is reduced as compared with a case where a shaft having a section almost equal to that of the holding part 7 is provided, and as a result, it is possible to reduce the capacity of the closed space around the substrate 9 and variation in the capacity and thereby achieve a more efficient processing. If the substrate 9 is broken inside the chamber body 6 of the thermal processing apparatus 1 having such a T-shaped structure, sometimes the broken pieces of the substrate 9 are scattered even on the chamber bottom 62 positioned immediately below the holding part 7. In the thermal processing apparatus 1, however, since maintenance of the chamber bottom 62 immediately below the holding part 7 can be performed without removing the holding part 7, it is possible to significantly reduce the time and labor required for the maintenance.

In the thermal processing apparatus 1, since the movement of the holding part 7 during the thermal processing for the substrate 9 and that during the maintenance are performed by the same holding-part moving mechanism 4, it is possible to simplify the structure of the apparatus.

In the thermal processing apparatus 1, since the substrate 9 is heated by irradiation of light emitted from the light emitting part 5 to allow the surface temperature of the substrate 9 to rise and fall in a short time, it is possible to achieve a processing which is hard to execute through a long heating, such as thinning of an insulating film such as an oxide film. The thermal processing apparatus 1 uses the flash lamps 51 as a light source, which allows the surface temperature of the substrate 9 to rise and fall in an extremely short time, and it is therefore possible to achieve a processing which requires heating for a still shorter time, such as suppressing of rediffusion of impurities in activation of impurities implanted by ion implantation.

Since the holding-part moving mechanism 4 allows manual movement of the holding part 7 with the manual moving part 49 during maintenance, the holding part 7 can be moved safely up to the maintenance position and it is therefore possible to prevent the operator from being jammed and ensure a safe maintenance.

Though the preferred embodiment of the present invention has been discussed above, the present invention is not limited to the above-discussed preferred embodiment, but allows various variations.

For example, in the light emitting part 5, the number of flash lamps 51 and layout and shape are not limited to those shown in the preferred embodiment but may be appropriately changed in accordance with conditions such as the size of the substrate 9 to be thermally processed. Krypton flash lamps may be used instead of the xenon flash lamps, and light sources other than flash lamps, such as halogen lamps, may be also used.

Like a case where halogen lamps are used as a light source for emitting light to the substrate 9, if the thermal processing of the substrate 9 is performed in a relatively longer time as compared with a case of using the flash lamps 51, in order to make the whole result of the thermal processing on all the substrates 9 uniform, a structure may be adopted in which the holding part 7 is rotated about the shaft 41 in the chamber 65.

Though it is preferable that the structure including the holding part 7 and the shaft 41 used for holding and vertically moving the holding part 7 should be a T-shaped structure in terms of reduction in capacity of the closed space around the substrate 9, the structure is not limited to the T-shaped one.

Though it is preferable that in the holding-part moving mechanism 4, the holding part 7 should be moved up and down manually with the manual moving part 49 during maintenance in terms of safety for operators, the holding part 7 may be moved up to the maintenance position by the motor 40 or other driving mechanisms if some safety measure is taken.

The bellows 47 serving to keep the chamber 65 airtight may have a free length corresponding to a range of movement of the holding part 7 (from the transferring position to the maintenance position), and in this case, it is possible to omit a step of attaching and detaching the bellows 47 to/from the shaft 41 during maintenance.

The vertical width of the gap 601 is not limited to the size shown in the above preferred embodiment, and only if the lower surface 77 of the holding part 7 is positioned higher than the upper surface 69 of the edge of the upper opening 60, the maintenance such as cleaning of the inside of the chamber body 6 can be executed from the gap 601 by using some tools (e.g., a hose connected to a suction pump, or the like).

In the thermal processing apparatus 1, processings with various heating operations, such as oxidation, anneal or CVD, other than activation of impurities may be performed on the substrate 9. The main heating for the substrate 9 may be performed by a method other than irradiation of light, or preheating may be omitted. For example, any processing with heating using only the hot plate 71 may be performed. The structure of the thermal processing apparatus 1 can be applied to a processing apparatus which performs processings on the substrate 9 without heating, and for example, it can be used in formation of a thin film such as an oxide film on the substrate 9 by simple reaction with a process gas, photo-assisted CVD or the like. The substrate to be processed is not limited to a semiconductor substrate, but the present invention can be applied to any processing for glass substrates used for flat panel displays such as liquid crystal displays or plasma displays.

While the invention has been shown and described in detail, the foregoing description is in all aspects illustrative and not restrictive. It is therefore understood that numerous modifications and variations can be devised without departing from the scope of the invention.

1. A substrate processing apparatus for processing a substrate in a chamber, comprising:
a chamber body forming a chamber which is a space for processing a substrate and having an opening in its upper portion;
a closing member attached to said opening, for closing said opening;
a holding part for holding a substrate in said chamber; and
a moving mechanism for moving a lower surface of said holding part up to a level higher than an upper surface of an edge of said opening while said closing member is not attached to said opening.

2. The substrate processing apparatus according to claim 1, wherein
another opening which is smaller than said holding part is provided in a lower portion of said chamber body, and
said moving mechanism comprises a shaft inserted to said another opening and connected to said lower surface of said holding part, moving up and down.

3. The substrate processing apparatus according to claim 1, wherein
said moving mechanism comprises a driving mechanism for moving said holding part up and down inside said chamber body during processing of a substrate.

4. The substrate processing apparatus according to claim 1, wherein
said lower surface of said holding part is moved by said moving mechanism up to a level higher than said upper surface of said edge of said opening by 100 mm or more.

5. The substrate processing apparatus according to claim 1, further comprising
a light emitting part for emitting light through said closing member to a substrate held by said holding part, to heat said substrate.

6. The substrate processing apparatus according to claim 5, wherein
said light emitting part comprises flash lamps.

7. The substrate processing apparatus according to claim 1, wherein
said lower surface of said holding part is moved manually up to a level higher than said upper surface of said edge of said opening.

8. A maintenance method used in a substrate processing apparatus for processing a substrate in a chamber, comprising the steps of:
removing a closing member used for closing an opening in an upper portion of a chamber body forming a chamber which is a space for processing a substrate;
moving a lower surface of a holding part for holding a substrate in said chamber up to a level higher than an upper surface of an edge of said opening; and
performing maintenance of the inside of said chamber through a gap between said lower surface of said holding part and said edge of said opening.

9. The maintenance method according to claim 8, wherein
said lower surface of said holding part is moved up to a level higher than said upper surface of said edge of said opening by 100 mm or more.

10. The maintenance method according to claim 8, wherein
said closing member passes light to be emitted to a substrate held by said holding part.

11. The maintenance method according to claim 10, wherein
said closing member passes light emitted from flash lamps.

12. The maintenance method according to claim 8, wherein
said lower surface of said holding part is manually moved up to a level higher than said upper surface of said edge of said opening.
